(19) United States
(12) Patent Application Publication
(10) Pub. No.: US 2025/0024734 A1
(43) Pub. Date: Jan. 16, 2025

(54) DISPLAY DEVICE AND METHOD FOR PROVIDING THE SAME

(71) Applicant: Samsung Display Co., LTD., Yongin-si (KR)

(72) Inventors: Jeong Seok LEE, Yongin-si (KR); Woo Yong SUNG, Yongin-si (KR); Hee Jun YANG, Yongin-si (KR)

(21) Appl. No.: 18/432,628

(22) Filed: Feb. 5, 2024

(30) Foreign Application Priority Data
Jul. 10, 2023 (KR) 10-2023-0088853

(51) Int. Cl. H10K 59/80; H10K 59/12; H10K 59/122; H10K 59/38; H10K 71/20; H10K 102/00

(52) U.S. Cl. CPC H10K 59/873; H10K 59/1201; H10K 59/122; H10K 59/38; H10K 71/231; H10K 2102/351

(57) ABSTRACT

A display device includes emission areas, light emitting elements in the emission areas, a first bank layer having side surfaces exposed to emission area openings, and a second bank layer which protrudes further than the side surfaces of the first bank layer at the emission area openings and includes an upper surface, a first inorganic pattern in a first emission area opening and spaced apart from the upper surface of the second bank layer, and a second inorganic pattern in a second emission area opening and spaced apart from each of the first inorganic pattern and the upper surface of the second bank layer, and a dam which is on the second bank layer between the first inorganic pattern and the second inorganic pattern and spaced apart therefrom.

This application claims priority to Korean Patent Application No. 10-2023-0088853 filed on Jul. 10, 2023, and all the benefits accruing therefrom under 35 U.S.C. 119, the contents of which in its entirety are herein incorporated by reference.

### BACKGROUND

### 1. Field

The present disclosure relates to a display device and a method for providing the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel, since each of pixels of the display panel includes light emitting elements that may self-emit light.

Display devices have been applied to glasses-type devices for providing virtual reality and augmented reality. The display device of such glasses-type device is implemented in a very small size of about two inches or less in order to be applied to the glasses-type device, but should have a high pixel integration degree in order to be implemented with high resolution. For example, the display device of a relatively small electronic device may have a high pixel integration degree of 400 pixels per inch (PPI) or more.

### SUMMARY

When a display device of an electronic device is implemented in a very small size but has relatively high pixel integration degree, planar areas of light emission areas in which light emitting elements of the display device are disposed are reduced or minimized. Thus, it is difficult to implement the light emitting elements separated from each other for each emission area through a mask process.

One or more embodiment of the present disclosure provide a display device capable of forming light emitting elements separated from each other for each emission area without a mask process.

Aspects of the present disclosure also provide a display device in which an emission deviation that may occur for each pixel due to permeation of an etchant into light emitting elements in an etching process performed during processes for fabrication of the display device is reduced.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a first pixel electrode and a second pixel electrode disposed to be spaced apart from each other on a substrate, a pixel defining film disposed on the substrate and exposing the first pixel electrode and the second pixel electrode, a first light emitting layer disposed on the first pixel electrode and a first common electrode disposed on the first light emitting layer, a second light emitting layer disposed on the second pixel electrode and a second common electrode disposed on the second light emitting layer, a first bank layer disposed on the pixel defining film, a second bank layer disposed on the first bank layer and having side surfaces protruding more than side surfaces of the first bank layer, a first inorganic layer disposed on the first common electrode and the second bank layer and spaced apart from an upper surface of the second bank layer, a second inorganic layer disposed on the second common electrode and the second bank layer, spaced apart from the upper surface of the second bank layer, and spaced apart from the first inorganic layer, and a dam disposed on the second bank layer and spaced apart from the first inorganic layer and the second inorganic layer.

The dam may not overlap the first inorganic layer and the second inorganic layer in a thickness direction of the substrate.

The display device may further include an organic encapsulation layer disposed in a space between the first inorganic layer and the upper surface of the second bank layer spaced apart from each other and a space between the second inorganic layer and the upper surface of the second bank layer spaced apart from each other.

A distance between the first inorganic layer and the dam may be about 0.75 to about 1.25 times a thickness of the first light emitting layer.

A distance between the first inorganic layer and the dam may be about 1000 angstroms (Å) to about 3000 Å.

A thickness of the first light emitting layer may be about 1500 Å to about 2500 Å.

A maximum vertical distance from the substrate to the dam may be smaller than a maximum vertical distance from the substrate to the first inorganic layer.

A thickness of the dam may be about 1000 Å to about 3000 Å.

The first common electrode and the second common electrode may be spaced apart from each other, and the first common electrode and the second common electrode may be in contact with the side surfaces of the first bank layer.

The dam may be made of a material different from that of the organic encapsulation layer.

The dam may include one or more selected from polyimide, polyamide, benzocyclobutene, a phenolic resin, an acrylic resin, a methacrylic resin, polyisoprene, a vinyl-based resin, an epoxy-based resin, a urethane-based resin, a cellulose-based resin, and a perylene-based resin.

The first inorganic layer may be in contact with a lower surface of the second bank layer adjacent to the first common electrode, and the second inorganic layer may be in contact with a lower surface of the second bank layer adjacent to the second common electrode.

The pixel defining film may be spaced apart from an upper surface of the first pixel electrode.

The display device may further include a residual pattern disposed in a space between the pixel defining film and an upper surface of the first pixel electrode spaced apart from each other.

According to an aspect of the present disclosure, a method for providing a display device includes forming (or providing) a plurality of pixel electrodes and sacrificial layers on a substrate, forming a pixel defining material layer on the sacrificial layers, forming a first bank material layer on the pixel defining material layer, and forming a second bank material layer on the first bank material layer, the plurality of pixel electrodes being spaced apart from each other, and the sacrificial layers being disposed on the pixel electrodes, exposing the pixel defining material layer by etching the first bank material layer and the second bank material layer in areas overlapping the pixel electrodes, etching side surfaces of the first bank material layer so that portions of a lower surface of the second bank material layer are exposed, forming a dam on the second bank material layer, exposing the pixel electrodes by etching the exposed pixel defining material layer and the sacrificial layers, and forming a first light emitting layer on a first pixel electrode of the pixel electrodes, forming a first common electrode on the first light emitting layer, and forming a first inorganic material layer on the first common electrode.

In the forming of the dam on the second bank material layer, a material of the dam may be applied onto the second bank layer through slit coating, spin coating, or inkjet printing and the dam is patterned through photolithography.

In the forming of the first light emitting layer on the first pixel electrode of the pixel electrodes and the forming of the first common electrode on the first light emitting layer, a first light emitting material layer separated from the first light emitting layer may be formed on the second bank material layer and the dam, and a first electrode material layer separated from the first common electrode is formed on the first light emitting material layer, and in the forming of the first inorganic material layer on the first common electrode, the first inorganic material layer connected without being disconnected may be formed on the first common electrode and the first electrode material layer.

The method for fabrication of a display device may further include etching a portion of the first inorganic material layer, exposing the dam by etching the first electrode material layer and the first light emitting material layer, and forming a second light emitting layer on a second pixel electrode of the pixel electrodes, forming a second common electrode on the second light emitting layer, and forming a second inorganic material layer on the second common electrode.

In the forming of the second light emitting layer on the second pixel electrode, a second light emitting material layer including the same material as the second light emitting layer may be formed between the first inorganic material layer and the dam.

In the etching of the portion of the first inorganic material layer, the portion of the first inorganic material layer may be removed through a dry etching process, and in the exposing of the dam by etching the first electrode material layer and the first light emitting material layer, the first electrode material layer and the first light emitting material layer may be removed through a wet etching process.

With a display device and a method for fabrication thereof according to an embodiment, a dam may be included between light emitting elements to prevent a radical of an etchant from permeating between a second bank layer and a first inorganic encapsulation layer in an etching process. Damage to the light emitting elements due to the etchant or moisture is prevented, and thus, a luminance difference between the light emitting elements may be reduced.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a cross-sectional view of the display device of FIG. 1;

FIG. 3 is a top plan view illustrating an arrangement of light emitting elements relative to first inorganic encapsulation layers, a second bank layer, and a dam of the display device according to an embodiment;

FIG. 4 is a cross-sectional view illustrating a portion of the display device according to an embodiment;

FIG. 5 is an enlarged cross-sectional view illustrating a first emission area and a second emission area, specifically, area A1 of FIG. 4;

FIG. 6 is a cross-sectional view illustrating a process in which an etchant permeates into a light emitting element by the absence of a dam structure;

FIG. 7 is a cross-sectional view illustrating a process in which permeation of an etchant is blocked in the display device according to an embodiment; and

FIGS. 8 to 18 are cross-sectional views sequentially illustrating processes for providing of the display device according to an embodiment.

### DETAILED DESCRIPTION

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being related to another element such as being “on” another layer or substrate, it can be directly on the other layer or substrate, or intervening layers may also be present. In contrast, when a layer is referred to as being related to another element such as being “directly on” another layer or substrate, no intervening layer is present therebetween.

The same reference numbers indicate the same components throughout the specification. For example, a reference number labeling a singular form of an element within the figures may be used to reference a plurality of the singular element within the text of the disclosure.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the accompanying drawings.

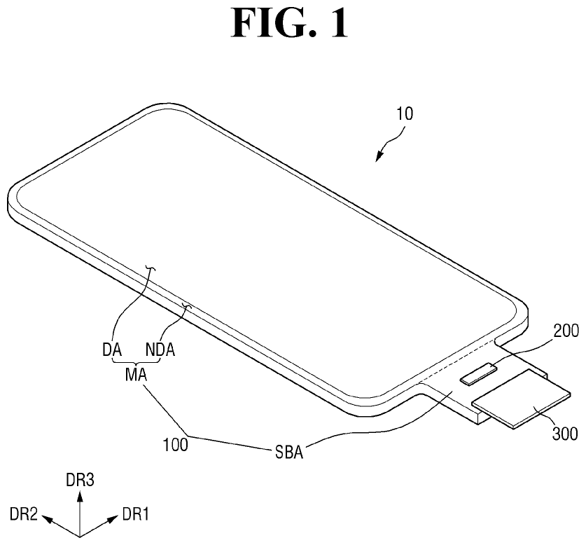

FIG. 1 is a perspective view illustrating a display device 10 according to an embodiment.

Referring to FIG. 1, a display device 10 according to an embodiment may be included in an electronic device to provide a display screen at which an image is displayed in the electronic device. The electronic device may refer to all electronic devices that provide a display screen at which an image is displayed. For example, televisions, laptop computers, monitors, billboards, the Internet of Things (IoT), mobile phones, smartphones, tablet personal computers (PCs), electronic watches, smart glasses, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the electronic device.

A shape of the display device 10 may be variously modified. For example, a planar shape of the display device 10 may have a shape similar to a rectangular shape having short sides in a first direction DR1 and long sides in the second direction DR2 intersecting the first direction DR1 to define a plane. In the plan view, a corner where the short side in the first direction DR1 and the long side in the second direction DR2 meet each other may be rounded with a curvature, but is not limited thereto, and may also be right-angled. The planar shape of the display device 10 in plan view is not limited to the rectangular shape, and may be a shape similar to other polygonal shapes, a circular shape, or an elliptical shape.

The display device 10 may include a display panel 100, a display driver 200, a circuit board 300, and a touch driver 400.

The display panel 100 may include a main area MA and a sub-area SBA adjacent to each other.

The main area MA may include a display area DA including pixels displaying an image, and a non-display area NDA which is adjacent to the display area DA such as being disposed around the display area DA in the plan view. The display area DA may emit light from a plurality of light emission areas and/or a plurality of opening areas. For example, the display panel 100 may include pixel circuits including switching elements, a pixel defining film defining the light emission areas and/or the opening areas, and self-light emitting elements.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

A plurality of pixels, a plurality of scan lines, a plurality of data lines, and a plurality of power lines may be disposed in the display area DA. Each of the plurality of pixels may be defined as a minimum unit emitting light, and each of a self-light emitting element described above may be in each of the pixels. The plurality of scan lines may supply scan signals received from a scan driver (not shown), to the plurality of pixels. The plurality of data lines may supply data voltages received from the display driver 200, to the plurality of pixels. The plurality of power lines may supply source voltages received from the display driver 200, to the plurality of pixels.

The non-display area NDA may be an area (e.g., a planar area) outside the display area DA or closer to an outer edge of the display device 10 than the display area DA. The non-display area NDA may be defined as an edge area of the main area MA of the display panel 100. The non-display area NDA may include the scan driver supplying the scan signals to the scan lines, and fan-out lines connecting the display driver 200 and the display area DA to each other.

The sub-area SBA may be an area extending from one side of the main area MA. The sub-area SBA may include a flexible material that may be bent, folded, and rolled. That is, the display device 10 and various components or layers thereof a the sub-area SBA may be bendable, foldable, rollable, etc. For example, the display device 10 which is bent at the sub-area SBA, the sub-area SBA may be disposed to overlap the main area MA in (or along) a thickness direction (e.g., the third direction DR3 crossing both of the first and second directions DR1 and DR2). The sub-area SBA may include the display driver 200 and pad parts of the display panel 100 at which the display panel 100 is connected to the circuit board 300. In another embodiment, the sub-area SBA may be omitted, and the display driver 200 and the pad parts may be disposed in the non-display area NDA.

The display driver 200 may output signals and voltages as electrical signals for driving the display panel 100 to activate the pixels, generate and/or emit light, display an image, etc. The display driver 200 may supply the data voltages to the data lines. The display driver 200 may supply the source voltages to the power lines and supply scan control signals to the scan driver. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be connected to the display panel 100 at the sub-area SBA, and may overlap the main area MA in the thickness direction (third direction DR3) by bending of the display panel 100 at the sub-area SBA. As another example, the display driver 200 may be mounted on the circuit board 300.

The circuit board 300 may be attached or connected to the display panel 100 at the pad parts of the display panel 100, such as by using an anisotropic conductive film (ACF). Lead lines of the circuit board 300 may be electrically connected to the pad parts of the display panel 100. The circuit board 300 may be a flexible printed circuit board, a printed circuit board, or a flexible film such as a chip on film.

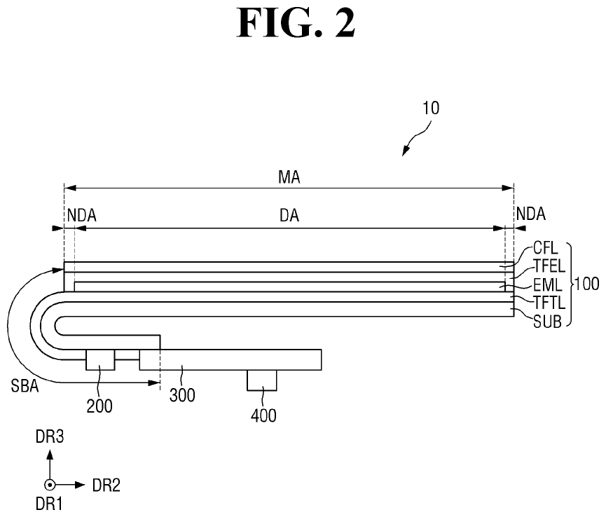

FIG. 2 is a cross-sectional view of the display device 10 of FIG. 1 viewed from the side. Specifically, FIG. 2 illustrates a side surface of the display device of FIG. 1 in a state in which the display device 10 is folded.

Referring to FIG. 2, the display panel 100 may include a substrate SUB, a thin film transistor layer TFTL as a circuit layer, a light emitting element layer EML, a thin film encapsulation layer TFEL as an encapsulation layer, and a color filter layer CFL.

The substrate SUB may be a base substrate or a base member. The substrate SUB may be a flexible substrate that may be bent, folded, and rolled. For example, the substrate SUB may include a polymer resin such as polyimide (PI), but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include scan lines, data lines, power lines, scan control lines, fan-out lines connecting the display driver 200 and the data lines to each other, and lead lines connecting the display driver 200 and the pad parts to each other. Each of the thin film transistors may include a semiconductor region, a source electrode, a drain electrode, and a gate electrode. For example, when the scan driver is formed on one side of the non-display area NDA of the display panel 100, the scan driver may include thin film transistors of the circuit layer.

The thin film transistor layer TFTL may be disposed in the display area DA, the non-display area NDA, and the sub-area SBA. The thin film transistors of each of the pixels, the scan lines, the data lines, and the power lines of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements each including a first electrode, a second electrode, and a light emitting layer to emit light, and a pixel defining film defining an area of the pixels. The plurality of light emitting elements of the light emitting element layer EML may be disposed in the display area DA. The light emitting element layer EML may be connected to the circuit layer for activating the pixels, generating and/or emit light, displaying an image, etc.

In an embodiment, the light emitting layer may be an organic light emitting layer including an organic material. The light emitting layer may include a hole transporting layer, an organic light emitting layer, and an electron transporting layer. When the first electrode of the light emitting element layer EML receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The thin film encapsulation layer TFEL may cover an upper surface and side surfaces of the light emitting element layer EML, and may protect the light emitting element layer EML. The thin film encapsulation layer TFEL may include at least one inorganic film and at least one organic film for encapsulating the light emitting element layer EML.

The color filter layer CFL may be disposed on the thin film encapsulation layer TFEL. The color filter layer CFL may include a plurality of color filters each corresponding to the plurality of emission areas. Each of the color filters may selectively transmit light of a specific wavelength therethrough and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the thin film encapsulation layer TFEL, the display device 10 may not require a separate substrate for the color filter layer CFL. Accordingly, a thickness of the display device 10 may be relatively small. The color filter layer CFL may contact the thin film encapsulation layer TFEL to form an interface therebetween.

In some embodiments, the display device 10 may further include an optical device which provides a function to the display device 10. The optical device may emit or receive light of infrared, ultraviolet, and visible light bands to provide the function. For example, the optical device may be an optical sensor sensing light incident on the display device 10, such as a proximity sensor, an illuminance sensor, a camera sensor, a fingerprint sensor, or an image sensor.

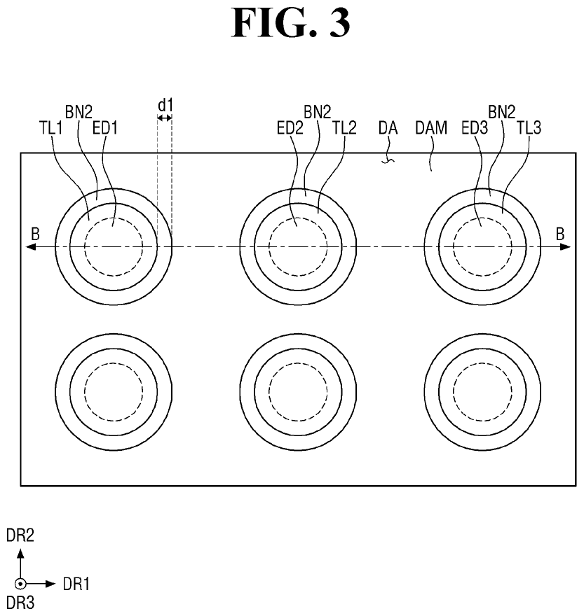

FIG. 3 is a plan view illustrating a portion of the display device 10 according to an embodiment. FIG. 3 is a plan view illustrating an areal arrangement of light emitting elements ED1, ED2, and ED3, first inorganic encapsulation layers TL1, TL2, and TL3 as a plurality of inorganic patterns, a second bank layer BN2, and a dam DAM in the display area DA of the display device 10.

Referring to FIG. 3, the second bank layer BN2 may cover the display area DA, but expose portions (e.g., underlying layers) of the display area DA to outside the second bank layer BN2. Openings (shown dotted line areas in FIG. 3) may be formed or provided in the second bank layer BN2 to define exposed areas that are not covered with material of the second bank layer BN2. The light emitting elements ED1, ED2, and ED3 may be disposed within the respective openings.

The first inorganic encapsulation layers TL1, TL2, and TL3 may cover the light emitting elements ED1, ED2, and ED3 within the respective openings, and may partially cover boundary portions of the second bank layer BN2 which define the openings. The dam DAM may be disposed to be respectively spaced apart from the first inorganic encapsulation layers TL1, TL2, and TL3 by a predetermined distance d1 on the second bank layer BN2. It has been illustrated in FIG. 3 that the exposed areas that are not covered with the second bank layer BN2 have a circular shape in the plan view, but the exposed areas that are not covered with the second bank layer BN2 may have a polygonal shape such as a triangular shape, a quadrangular shape, or a hexagonal shape, and a shape of the first inorganic encapsulation layers TL1, TL2, and TL3 covering the exposed areas and peripheral portions of the exposed areas may also be changed.

The first inorganic encapsulation layers TL1, TL2, and TL3 respectively extend from within a volume of the opening, to outside the opening and overlapping peripheral portions of the second bank layer BN2 which define the openings. The extended portions of the first inorganic encapsulation layers TL1, TL2, and TL3 may extend further from the light emitting elements ED1, ED2, and ED3 than the second bank layer BN2. The extended portions (wings) of the first inorganic encapsulation layers TL1, TL2, and TL3 may be disposed at a level (or plane) above the second bank layer BN2, and the light emitting elements ED1, ED2, and ED3 may be disposed at a level below the second bank layer BN2.

The exposed areas that are not covered with the second bank layer BN2 may be disposed to be spaced apart from each other in the first direction DR1 and may also be disposed to be spaced apart from each other in the second direction DR2, along the plane defined by the first and second direction DR1 and DR2. A shape and an arrangement of the exposed areas that are not covered with the second bank layer BN2 are not limited to those illustrated in FIG. 3, and the exposed areas that are not covered with the second bank layer BN2 may be disposed in a PENTILE™ type.

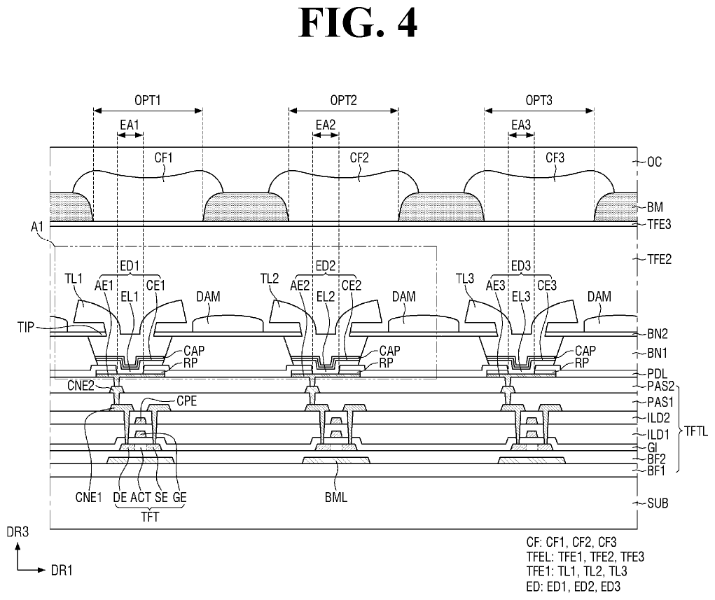

FIG. 4 is a cross-sectional view illustrating a portion of the display device 10 according to an embodiment. Specifically, FIG. 4 is a cross-sectional view taken along line B-B′ of FIG. 3, and illustrates an organic encapsulation layer TFE2, a second inorganic encapsulation layer TFE3, color filters CF1, CF2, and CF3, a light blocking layer BM including a plurality of light blocking patterns spaced apart from each other, and an overcoat layer OC that are disposed above the plan view of FIG. 3. FIG. 4 illustrates cross-sections of the substrate SUB, the thin film transistor layer TFTL, the light emitting element layer EML, the thin film encapsulation layer TFEL, and the color filter layer CFL.

The thin film transistor layer TFTL may include a first buffer layer BF1, a bottom metal layer BML including solid material portions spaced apart from each other, a second buffer layer BF2, thin film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include a plurality of inorganic films that are stacked.

The bottom metal layer BML may be disposed on the first buffer layer BF1. For example, the bottom metal layer BML may be formed as a single material layer or multiple material layers made of any one of molybdenum (Mo), aluminum (Al), chromium (Cr), gold (Au), titanium (Ti), nickel (Ni), neodymium (Nd), and copper (Cu) and alloys thereof.

The second buffer layer BF2 may cover the first buffer layer BF1 and the bottom metal layer BML. The second buffer layer BF2 may include an inorganic film capable of preventing permeation of air or moisture. For example, the second buffer layer BF2 may include a plurality of inorganic films that are stacked.

The thin film transistor TFT may be disposed on the second buffer layer BF2, and may constitute a pixel circuit of each of the plurality of pixels. For example, the thin film transistor TFT may be a driving transistor and/or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the bottom metal layer BML and the gate electrode GE in the thickness direction DR3, and may be insulated from the gate electrode GE by the gate insulating layer GI. A material of the semiconductor layer ACT in portions of the semiconductor layer ACT may be conductive to form the source electrode SE and the drain electrode DE.

The gate electrode GE may be disposed on the gate insulating layer GI. The gate electrode GE may overlap the semiconductor layer ACT in the thickness direction DR3 with the gate insulating layer GI interposed therebetween.

The gate insulating layer GI may be disposed on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include (or define) contact holes through which the first connection electrodes CNE1 penetrate.

The first interlayer insulating layer ILD1 may cover the gate electrode GE and the gate insulating layer GI. The first interlayer insulating layer ILD1 may include contact holes through which the first connection electrodes CNE1 penetrate. The contact holes of the first interlayer insulating layer ILD1 may be connected to or aligned with the contact holes of the gate insulating layer GI and contact holes of the second interlayer insulating layer ILD2, respectively, to define single contact holes penetrating a collective insulating layer IL2, IL1 and GI.

The capacitor electrodes CPE may be disposed on the first interlayer insulating layer ILD1. The capacitor electrode CPE may overlap the gate electrode GE in the thickness direction DR3. The capacitor electrode CPE and the gate electrode GE may form an electrical capacitance.

The second interlayer insulating layer ILD2 may cover the capacitor electrodes CPE and the first interlayer insulating layer ILD1. The second interlayer insulating layer ILD2 may include contact holes through which the first connection electrodes CNE1 penetrate. The contact holes of the second interlayer insulating layer ILD2 may be connected to the contact holes of the first interlayer insulating layer ILD1 and the contact holes of the gate insulating layer GI.

The first connection electrodes CNE1 may be disposed on the second interlayer insulating layer ILD2. The first connection electrode CNE1 may electrically connect the drain electrode DE of the thin film transistor TFT and the second connection electrode CNE2 to each other. The first connection electrode CNE1 may be inserted into or pass through the contact holes formed in the second interlayer insulating layer ILD2, the first interlayer insulating layer ILD1, and the gate insulating layer GI to be in contact with the drain electrode DE of the thin film transistor TFT within a respective single contact hole.

The first passivation layer PAS1 may cover the first connection electrode CNE1 and the second interlayer insulating layer ILD2. The first passivation layer PAS1 may protect the thin film transistor TFT. The first passivation layer PAS1 may include contact holes through which the second connection electrodes CNE2 penetrate.

The second connection electrodes CNE2 may be disposed on the first passivation layer PAS1. The second connection electrodes CNE2 may electrically connect the first connection electrodes CNE1 and pixel electrodes AE1, AE2, and AE3 of the light emitting elements ED to each other. The second connection electrode CNE2 may be inserted into the contact hole formed in the first passivation layer PAS1 to be in contact with the first connection electrode CNE1.

The second passivation layer PAS2 may cover the second connection electrodes CNE2 and the first passivation layer PAS1. The second passivation layer PAS2 may include contact holes through which the pixel electrodes AE1, AE2, and AE3 of the light emitting elements ED penetrate.

The light emitting element layer EML may be disposed on the thin film transistor layer TFTL. The light emitting element layer EML may include the light emitting elements ED, a pixel defining film PDL, capping layers CAP as capping patterns, and a bank structure BNS including bank patterns. The light emitting elements ED may include the pixel electrodes AE1, AE2, and AE3, light emitting layers EL1, EL2, and EL3, and common electrodes CE1, CE2, and CE3, respectively.

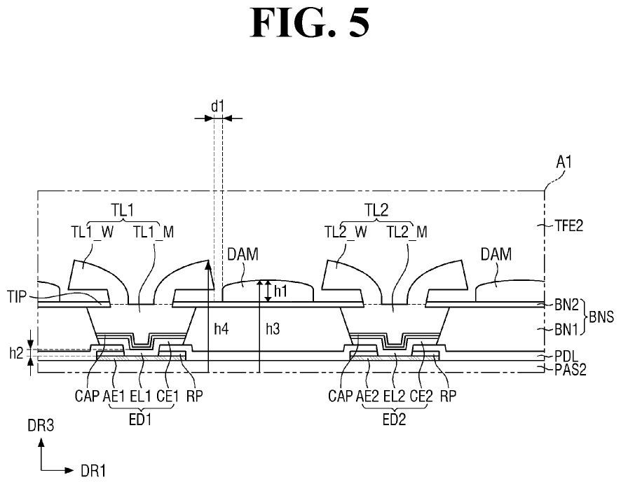

FIG. 5 is an enlarged view illustrating a first emission area EA1 and a second emission area EA2, specifically, area A1 of FIG. 4.

Referring to FIG. 5 in addition FIG. 4, the display device 10 may include a plurality of emission areas EA1, EA2, and EA3 disposed in the display area DA. The emission areas EA1, EA2, and EA3 may include or define planar areas at which light is emitted from the light emitting elements ED1, ED2, and ED3 and passes to the color filter layer CFL in the third direction DR3. The emission areas EA1, EA2, and EA3 may include first emission areas EA1, second emission areas EA2, and third emission areas EA3 that are spaced apart from each other and emit light of the same or different colors.

In an embodiment, areas or sizes of the first to third emission areas EA1, EA2, and EA3 may be the same as each other. For example, in the display device 10, the first emission area EA1, the second emission area EA2, and the third emission area EA3 may have the same planar area. However, the present disclosure is not limited thereto. In the display device 10, areas or sizes of the first to third emission areas EA1, EA2, and EA3 may be different from each other. For example, a planar area of the second emission area EA2 may be greater than planar areas of the first emission area EA1 and the third emission area EA3, and a planar area of the third emission area EA3 may be greater than a planar area of the first emission area EA1. Intensities of the light emitted from the emission areas EA1, EA2, and EA3 may be changed depending on the planar areas of the emission areas EA1, EA2, and EA3, and a color feeling of a screen displayed on the display device 10 may be controlled by adjusting the planar areas of the emission area EA1, EA2, and EA3. In an embodiment of FIG. 4, it has been illustrated that the planar areas of the emission areas EA1, EA2, and EA3 are the same as each other, but the present disclosure is not limited thereto.

In the display device 10, one first emission area EA1, one second emission area EA2, and one third emission area EA3 disposed adjacent to each other may form one pixel group. One pixel group may include each of the emission areas EA1, EA2, and EA3 emitting light of different colors to express a white gradation. However, the present disclosure is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, and the like.

A plurality of openings formed in the bank structure BNS of the light emitting element layer EML are defined along a boundary of the bank structure BNS. That is, a sidewall or side surface of material portions of the bank structure BNS may define the openings. A first bank layer BN1 and a second bank layer BN2 of the bank structure BNS may have a planar shape which extends along a boundary of the emission areas EA1, EA2, and EA3 such as to surround the emission areas EA1, EA2, and EA3. A planar size or shape of the openings may include the planar size or shape of the first to third emission areas EA1, EA2, and EA3 disposed thercin.

The display device 10 may include a plurality of light emitting elements ED1, ED2, and ED3 disposed in different emission areas EA1, EA2, and EA3, respectively. The light emitting elements ED1, ED2, and ED3 may include a first light emitting element ED1 disposed in the first emission area EA1, a second light emitting element ED2 disposed in the second emission area EA2, and a third light emitting element ED3 disposed in the third emission area EA3.

The light emitting elements ED1, ED2, and ED3 may include pixel electrodes AE1, AE2, and AE3, light emitting layers EL1, EL2, and EL3, and common electrodes CE1, CE2, and CE3, respectively. The light emitting elements ED1, ED2, and ED3 disposed in the different emission areas EA1, EA2, and EA3 may emit light of different colors depending on materials of the light emitting layers EL1, EL2, and EL3, respectively. For example, the first light emitting element ED1 disposed in the first emission area EA1 may emit first light, which is red light, having a peak wavelength in the range of about 610 nanometers (nm) to about 650 nm, the second light emitting element ED2 disposed in the second emission area EA2 may emit second light, which is green light, having a peak wavelength in the range of about 510 nm to about 550 nm, and the third light emitting element ED3 disposed in the third emission area EA3 may emit third light, which is blue light, having a peak wavelength in the range of about 440 nm to about 480 nm. The first to third emission areas EA1, EA2, and EA3 constituting one pixel (or one pixel group) may include the light emitting elements ED1, ED2, and ED3 emitting the light of the different colors to express a white gradation at the one pixel. Alternatively, the light emitting layers EL1, EL2, and EL3 may include two or more materials emitting the light of the different colors, such that one light emitting layer may emit mixed light. For example, the light emitting layers EL1, EL2, and EL3 may include both of a red light emitting material and a green light emitting material to cmit yellow light or include all of a red light emitting material, a green light emitting material, and a blue light emitting material to emit white light.

The pixel electrodes AE1, AE2, and AE3 may be disposed on the second passivation layer PAS2. The pixel electrodes AE1, AE2, and AE3 may be disposed in the plurality of emission areas EA1, EA2, and EA3, respectively. The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be disposed to be spaced apart from each other along the second passivation layer PAS2. It has been illustrated in FIG. 4 that the first to third pixel electrodes AE1, AE2, and AE3 are spaced apart from each other in the first direction DR1, but the present disclosure is not limited thereto, and the first to third pixel electrodes AE1, AE2, and AE3 may be spaced apart from each other in any one direction within a plane formed by the first direction DR1 and the second direction DR2 crossing each other.

The pixel electrodes AE1, AE2, and AE3 may be electrically connected to the drain electrodes DE of respective the thin film transistors TFT, a connection electrode having the first and second connection electrodes CNE1 and CNE2. Outer edges of the pixel electrodes AE1, AE2, and AE3 spaced apart from each other are covered by a material portion of the pixel defining film PDL, such that the first to third pixel electrodes AE1, AE2, and AE3 may be insulated from each other.

The pixel electrodes AE1, AE2, and AE3 may include a transparent electrode material and/or a conductive metal material. The conductive metal material may be one or more of silver (Ag), copper (Cu), aluminum (Al), nickel (Ni), lanthanum (La), titanium (Ti), and titanium nitride (TiN). The transparent electrode material may be one or more of indium tin oxide (ITO), indium zinc oxide (IZO), and indium tin zinc oxide (ITZO). The pixel electrodes AE1, AE2, and AE3 may have a multilayer structure of the transparent electrode material and the conductive metal material.

The pixel defining film PDL may be disposed on the second passivation layer PAS2, residual patterns RP and the pixel electrodes AE1, AE2, and AE3. The pixel defining film PDL may be entirely disposed on the second passivation layer PAS2, but may expose portions of upper surfaces of the pixel electrodes AE1, AE2, and AE3 to outside the pixel defining film PDL, by covering outer side surfaces of the pixel electrodes AE1, AE2, and AE3 and the residual patterns RP. For example, the pixel defining film PDL may expose the first pixel electrode AE1 in the first emission area EA1 to outside the pixel defining layer, and a first light emitting layer EL1 may be directly disposed on the first pixel electrode AE1 exposed by the pixel defining layer.

The pixel defining film PDL as the pixel defining layer may include an inorganic insulating material. The pixel defining film PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, and an amorphous silicon layer, but is not limited thereto. Material portions of the pixel defining layer may be spaced apart from each other to define a pixel opening at the pixel defining layer.

According to an embodiment, the pixel defining film PDL may be disposed on the pixel electrodes AE1, AE2, and AE3, but may be spaced apart from the upper surfaces of the pixel electrodes AE1, AE2, and AE3. Within the openings of the bank structure BSN, the pixel defining film PDL may not be in direct contact with the upper surfaces of the pixel electrodes AE1, AE2, and AE3 while partially overlapping the upper surfaces of the pixel electrodes AE1, AE2, and AE3 in the thickness direction DR3 of the substrate SUB, and the residual patterns RP may be disposed between the pixel defining film PDL and the upper surfaces of the pixel electrodes AE1, AE2, and AE3. However, the pixel defining film PDL may be in direct contact with outer side surfaces of the pixel electrodes AE1, AE2, and AE3.

Each of the pixel defining film PDL and the second bank layer BN2 may have a side surface which defines an opening at a respective emission area. Side surfaces of the pixel defining film PDL may protrude more than side surfaces of the second bank layer BN2 toward the emission areas EA1, EA2, and EA3. That is, the pixel defining layer extends further toward the emission areas than the second bank layer BN2, such that the side surface of the pixel defining layer is closer to a respective emission layer than the side surface of the second bank layer BN2. Each of the pixel defining layer and the second bank layer BN2 may extend further than a side surface of the first bank layer BN1.

The residual patterns RP may be disposed on or along outer edges of the pixel electrodes AE1, AE2, and AE3, respectively. The pixel defining film PDL may not be in direct contact with the upper surfaces of the pixel electrodes AE1, AE2, and AE3 due to the residual patterns RP. As used herein, not being in contact may exclude edge or point contact. For example, within the opening of the bank structure BNS, the pixel defining layer is spaced apart from the respective pixel electrode by the residual patterns RP.

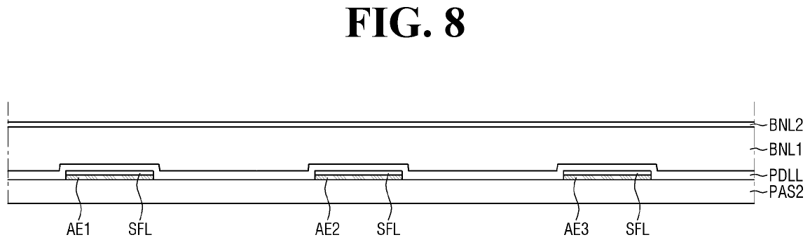

The residual patterns RP may be formed by removing material portions of sacrificial layers SFL (see FIG. 8) disposed on the pixel electrodes AE1, AE2, and AE3 in processes of fabrication of the display device 10, such that the residual patterns RP are remaining portions of the material of the sacrificial layers SFL. The residual pattern RP may include a metal, an oxide semiconductor, or a transparent conductive oxide (TCO). Only a case where inner side surfaces of the residual patterns RP toward the emission areas EA1, EA2, and EA3 are aligned with the inner side surfaces of the pixel defining film PDL has been illustrated in the drawings, but the present disclosure is not limited thereto. The inner side surfaces of the residual patterns RP may protrude more than the inner side surfaces of the pixel defining film PDL toward the emission areas EA1, EA2, and EA3 or may be depressed more than the inner side surfaces of the pixel defining film PDL.

The light emitting layers EL1, EL2, and EL3 may be disposed on the pixel electrodes AE1, AE2, and AE3, respectively. The light emitting layers EL1, EL2, and EL3 may be organic light emitting layers or patterns made of an organic material, and may be formed on the pixel electrodes AE1, AE2, and AE3, respectively, through a deposition process. The light emitting layers EL1, EL2, and EL3 may have a multilayer structure, and a hole injection material, a hole transporting material, a light emitting material, an electron transporting material, and/or an electron injection material may constitute layers of the light emitting layers EL1, EL2, and EL3, respectively. When the thin film transistors TFT apply predetermined voltages to the pixel electrodes AE1, AE2, and AE3 of the light emitting elements ED1, ED2, and ED3, and the common electrodes CE1, CE2, and CE3 of the light emitting elements ED1, ED2, and ED3 receives a common voltage or a cathode voltage, holes and electrons may be injected and transported, respectively, and may be combined with each other in the light emitting layers EL1, EL2, and EL3 to emit light.

The light emitting layers EL1, EL2, and EL3 may include a first light emitting layer EL1, a second light emitting layer EL2, and a third light emitting layer EL3 each disposed in the different emission areas EA1, EA2, and EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. A plurality of light emitting layers EL1, EL2, and EL3 may emit light of different colors, respectively, or one light emitting layer EL1, EL2, or EL3 may emit mixed light. In an embodiment, the first light emitting layer EL1 may emit red light, the second light emitting layer EL2 may emit green light, and the third light emitting layer EL3 may emit blue light. In another embodiment, the first light emitting layer EL1 may emit yellow light, which is mixed light of red light and green light, and the second light emitting layer EL2 may emit blue light. In still another embodiment, the first light emitting layer EL1 may emit white light, which is mixed light of red light, green light, and blue light.

In an embodiment, a second thickness h2 of the light emitting layers EL1, EL2, and EL3 may be about 1500 angstroms (Å) to about 2500 Å. The thickness of the light emitting layers EL1, EL2, and EL3 may be changed depending on the color of the light emitted from the light emitting layers EL1, EL2, and EL3. The second thickness h2 of a respective light emitting layer may be defined by a thickness portion of the light emitting layer within the pixel opening of the pixel defining layer, along the third direction DR3. The second thickness h2 may also be defined in a direction normal to a surface along which the light emitting layer extends (like the side or upper surface of the pixel defining layer).

The light emitting layers EL1, EL2, and EL3 may be disposed on an upper surface of the pixel defining film PDL. The light emitting layers EL1, EL2, and EL3 may be disposed in spaces defined between the pixel electrodes AE1, AE2, and AE3 together with the inner surfaces of the pixel defining film PDL. The light emitting layers EL1, EL2, and EL3 may be in contact with the pixel defining film PDL, the residual patterns RP, and the pixel electrodes AE1, AE2, and AE3.

The common electrodes CE1, CE2, and CE3 may be disposed on the light emitting layers EL1, EL2, and EL3, respectively. The common electrodes CE1, CE2, and CE3 may include a transparent conductive material to emit the light generated from the light emitting layers EL1, EL2, and EL3. The common electrodes CE1, CE2, and CE3 may receive a common voltage or a low potential voltage. When the pixel electrodes AE1, AE2, and AE3 receive voltages corresponding to data voltages and the common electrodes CE1, CE2, and CE3 receive the low potential voltage, potential differences are formed between the pixel electrodes AE1, AE2, and AE3 and the common electrodes CE1, CE2, and CE3, such that the light emitting layers EL1, EL2, and EL3 may emit the light.

The common electrodes CE1, CE2, and CE3 may include a first common electrode CE1, a second common electrode CE2, and a third common electrode CE3 each disposed in the different emission areas EA1, EA2, and EA3. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3. The first to third common electrodes CE1, CE2, and CE3 may be spaced apart from each other.

The capping layers CAP may be disposed on the common electrodes CE1, CE2, and CE3. The capping layers CAP may include an organic or inorganic insulating material and cover patterns disposed on the light emitting elements ED1, ED2, and ED3. The capping layers CAP may prevent the light emitting elements ED1, ED2, and ED3 from being damaged by external air. In an embodiment, the capping layer CAP may include an organic material such as α-NPD, NPB, TPD, m-MTDATA, Alq₃, LiF, and/or CuPc, or an inorganic material such as aluminum oxide, titanium oxide, tantalum oxide, hafnium oxide, zinc oxide, silicon oxide, silicon nitride, and/or silicon oxynitride.

The display device 10 may include a plurality of bank structures BNS of a bank layer which are respectively disposed on material portions of the pixel defining film PDL. The bank structure BNS may have a structure in which bank layers BN1 and BN2 including different materials from each other are sequentially stacked in a direction away from the pixel defining layer. The material portions of the bank structure BNS may define the plurality of openings having an area including the areas of the emission areas EA1, EA2, and EA3, and may be disposed so as to overlap a light blocking layer BM to be described later. The light emitting elements ED1, ED2, and ED3 of the display device 10 may be disposed to overlap the openings of the bank structure BNS.

The bank structure BNS may include a first bank layer BN1 and a second bank layer BN2 that are sequentially stacked on the pixel defining film PDL.

The first bank layer BN1 may be disposed on the pixel defining film PDL. Inner side surfaces of the first bank layer BN1 may be recessed from the inner side surfaces of the pixel defining film PDL in a direction away from the emission areas EA1, EA2, and EA3. The inner side surfaces of the first bank layer BN1 may be recessed from the inner side surfaces of a second bank layer BN2 to be described later in the direction away from the emission areas EA1, EA2, and EA3.

According to an embodiment, the first bank layer BN1 may include a metal material. In an embodiment, the first bank layer BN1 may include aluminum (Al) or an alloy of aluminum (Al).

In an embodiment, a thickness of the first bank layer BN1 may be in the range of about 4000 Å to about 7000 Å. When the thickness of the first bank layer BN1 is in the above range, the light emitting layers EL1, EL2, and EL3 and the common electrodes CE1, CE2, and CE3 spaced apart from each other may be formed through deposition and etching processes rather than a mask process.

According to an embodiment, the common electrodes CE1, CE2, and CE3 may be in direct contact with the inner side surfaces of the first bank layer BN1. The common electrodes CE1, CE2, and CE3 of different light emitting elements ED1, ED2, and ED3 may be in direct contact with the first bank layer BN1, respectively, and the first bank layer BN1 may include the metal material, such that the common electrodes CE1, CE2, and CE3 may be electrically connected to each other through the first bank layer BN1.

The light emitting layers EL1, EL2, and EL3 may be in direct contact with the inner side surfaces of the first bank layer BN1. A contact area between the common electrodes CE1, CE2, and CE3 and the inner side surfaces of the first bank layer BN1 may be greater than a contact area between the light emitting layers EL1, EL2, and EL3 and the side surfaces of the first bank layer BN1. Referring to FIG. 5, for example, the contact area may be a planar along a plane defined along the second and third direction DR2 and DR3. The common electrodes CE1, CE2, and CE3 may be disposed to have a greater contact area than the light emitting layers EL1, EL2, and EL3 with respect to the inner side surfaces of the first bank layer BN1. The common electrodes CE1, CE2, and CE3 may extend further along the inner side surfaces of the first bank layer BN1, in the third direction DR3, than the light emitting layers EL1, EL2, and EL3 to be disposed up to a greater height than the light emitting layers EL1, EL2, and EL3 along the side surfaces of the first bank layer BN1. Since the common electrodes CE1, CE2, and CE3 of the different light emitting elements ED1, ED2, and ED3 are electrically connected to each other through the first bank layer BN1, it may be advantageous that the common electrodes CE1, CE2, and CE3 are in contact with the first bank layer BN1 in a greater planar area.

The second bank layer BN2 may be disposed on the first bank layer BN1. The second bank layer BN2 may include tips TIP, which are extended portions of the second bank layer BN2 which protrude from the inner side surface of the first bank layer BN1. The inner side surfaces of the second bank layer BN2 which define distal ends of the tips TIP may be closer to the emission areas EA1, EA2, and EA3 than the inner side surfaces of the first bank layer BN1.

The side surfaces of the second bank layer BN2 have a shape in which they protrude more than the side surfaces of the first bank layer BN1, in a direction toward the emission areas EA1, EA2, and EA3. Accordingly, undercut structures of the first bank layer BN1 may be formed under the tips TIP of the second bank layer BN2.

In the display device 10 according to an embodiment, the bank structure BNS includes the tips TIP protruding toward the emission areas EA1, EA2, and EA3. Thus, the light emitting layers EL1, EL2, and EL3 and the common electrodes CE1, CE2, and CE3 may be formed at separated patterns through deposition and etching processes rather than the mask process. In addition, it is possible to form different layers or patterns individually in the different emission areas EA1, EA2, and EA3 even through a deposition process. For example, even though the light emitting layers EL1, EL2, and EL3 and the common electrodes CE1, CE2, and CE3 of the light emitting elements ED1, ED2, and ED3 are formed through a deposition process that does not use the mask, deposited materials may be disconnected from each other with the bank structure BNS interposed therebetween by the tips TIP of the second bank layer BN2 rather than being connected to each other between the emission areas EA1, EA2, and EA3. It is possible to form the different layers individually as separated patterns in the different emission areas EA1, EA2, and EA3 through a process of forming a material layer for forming a specific layer on an entirety of the display device 10 and then etching and removing a layer formed in unwanted areas. In the display device 10, through the deposition and etching processes without using the mask process, the different light emitting elements ED1, ED2, and ED3 may be formed for each of the emission areas EA1, EA2, and EA3, an unnecessary component may be omitted from the display device 10, and an area of the non-display area NDA may be minimized.

A side surface shape of the bank structure BNS having the undercut may be a structure formed due to a difference in etch rate between materials of the first and second bank layers BN1 and BN2 in an etching process since the first and second bank layers BN1 and BN2 include different materials. According to an embodiment, the second bank layer BN2 may include a material having an etch rate slower or lower than that of the first bank layer BN1, and the first bank layer BN1 may be etched more than the second bank layer BN2 in the etching process, such that lower surfaces of the tips TIP of the second bank layer BN2 may be exposed at the openings in the bank structure BNS and undercuts may be formed by the tips TIP of the second bank layer BN2 together with the inner side surfaces of the first bank layer BN1.

The second bank layer BN2 may include a metal material different from the metal material of the first bank layer BN1. The metal material of the second bank layer BN2 may be any material that is removed together with the metal material of the first bank layer BN1 by dry etching, but has an etch rate much slower from that of the first bank layer BN1 or is not etched with respect to wet etching. In an embodiment, the first bank layer BN1 may include aluminum (Al), and the second bank layer BN2 may include titanium (Ti).

The tips TIP of the second bank layer BN2 may overlap the common electrodes CE1, CE2, and CE3 in a third direction DR3 perpendicular to the substrate SUB. In addition, the tips TIP of the second bank layer BN2 may overlap the light emitting layers EL1, EL2, and EL3 in the third direction DR3 perpendicular to the substrate SUB. In addition, the tips TIP of the second bank layer BN2 may overlap the pixel defining film PDL in the third direction DR3 perpendicular to the substrate SUB. The common electrodes CE1, CE2, and CE3 may be formed as patterns under the lower surfaces of the tips TIP of the second bank layer BN2. Along the thickness direction of the display panel 100, a maximum distance from the substrate SUB to each of the common electrodes CE1, CE2, and CE3 may be smaller than a minimum distance from the substrate SUB to the second bank layer BN2.

The thin film encapsulation layer TFEL may be disposed on the light emitting elements ED1, ED2, and ED3 and the bank structure BNS, and may cover the plurality of light emitting elements ED1, ED2, and ED3 and the bank structure BNS. The thin film encapsulation layer TFEL may include at least one inorganic film to prevent oxygen or moisture from permeating into the light emitting element layer EML. The thin film encapsulation layer TFEL may include at least one organic film to protect the light emitting element layer EML from foreign substances such as dust.

In an embodiment, the thin film encapsulation layer TFEL may include a first inorganic encapsulation layer TFE1, an organic encapsulation layer TFE2, and a second inorganic encapsulation layer TFE3 that are sequentially stacked.

Each of the first inorganic encapsulation layer TFE1 and the second inorganic encapsulation layer TFE3 may include one or more inorganic insulating materials. The inorganic insulating material may be any one of silicon oxide, silicon nitride, and silicon oxynitride, and may be, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic resin, an epoxy-based resin, polyimide, polyethylene, and the like. For example, the organic encapsulation layer TFE2 may include an acrylic resin such as polymethyl methacrylate or polyacrylic acid. The organic encapsulation layer TFE2 may be formed by curing a monomer or applying a polymer.

The first inorganic encapsulation layer TFE1 may be disposed on the light emitting elements ED1, ED2, and ED3 and the bank structure BNS. The first inorganic encapsulation layer TFE1 may include a first inorganic layer TL1, a second inorganic layer TL2, and a third inorganic layer TL3 respectively disposed to correspond to the different emission areas EA1, EA2, and EA3. The first inorganic layer TL1, the second inorganic layer TL2, and the third inorganic layer TL3 may include an inorganic insulating material and cover the light emitting elements ED1, ED2, and ED3, respectively. The first inorganic layer TL1, the second inorganic layer TL2, and the third inorganic layer TL3 may prevent the light emitting elements ED1, ED2, and ED3 from being damaged by external air.

The first inorganic encapsulation layers TFE1 may be formed through chemical vapor deposition (CVD), and may thus be formed along steps or profiles of layers on which they are deposited. For example, the first inorganic layer TL1, the second inorganic layer TL2, and the third inorganic layer TL3 may form thin films even along the lower surfaces of the second bank layer BN2 which define the tips TIP of the bank structure BNS. It has been illustrated in FIGS. 4 to 6 that the first inorganic encapsulation layers TL1, TL2, and TL3 seal the light emitting elements ED1, ED2, and ED3 along outer surfaces of the light emitting elements ED1, ED2, and ED3 at a non-uniform thickness, but the first inorganic encapsulation layers TL1, TL2, and TL3 may be disposed along an upper surface, side surfaces and a lower surface of the second bank layer BN2, inner side surfaces of the first bank layer BN1, and upper surfaces of the common electrodes CE1, CE2, and CE3 at a uniform thickness.

The first inorganic layer TL1 may not overlap the second emission area EA2 and the third emission area EA3, and may be disposed only in the first emission area EA1 and on a portion of the bank structure BNS which is closest to and extends around the first emission area EA1. The second inorganic layer TL2 may not overlap the first emission area EA1 and the third emission area EA3, and may be disposed only in the second emission area EA2 and on a portion of the bank structure BNS which is closest to and extends around the second emission area EA2. The third inorganic layer TL3 may not overlap the first emission area EA1 and the second emission area EA2, and may be disposed only in the third emission area EA3 and on the bank structure BNS around the third emission area EA3.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2, and the third inorganic layer TL3 may be disposed to be spaced apart from each other on the bank structure BNS.

The first inorganic encapsulation layers TL1, TL2, and TL3 may include main portions TL1_M, TL2_M, and TL3_M surrounded by the bank structure BNS and wing portions TL1_W, TL2_W, and TL3_W which protrude from the main portions TL1_M, TL2_M, and TL3_M, respectively. A respective main portion and the wing portion protruded therefrom (dotted line boundary shown in FIG. 5 for example) may form a single, unitary pattern. The main portions TL1_M, TL2_M, and TL3_M of the first inorganic encapsulation layers TL1, TL2, and TL3 may be in contact with the lower surface of the second bank layer BN2 and the side surfaces (e.g., the inner sidewall) of the first bank layer BN1, and may cover the capping layers CAP and the common electrodes CE1, CE2, and CE3. The wing portions TL1_W, TL2_W, and TL3_W of the first inorganic encapsulation layers TL1, TL2, and TL3 may have a wing shape in cross-sectional view. The wing portions TL1_W, TL2_W, and TL3_W of the first inorganic encapsulation layers TL1, TL2, and TL3 may be disposed on the second bank layer BN2, but be spaced apart from the upper surface of the second bank layer BN2 to have undercut structures. The wing portions TL1_W, TL2_W, and TL3_W may overlap the second bank layer BN2 in the third direction DR3 (e.g., the thickness direction) of the substrate SUB. Spaces between the wing portions TL1_W, TL2_W, and TL3_W of the first inorganic encapsulation layers TL1, TL2, and TL3, and the second bank layer BN2 spaced apart from each other, may be spaces or gaps in which light emitting materials and electrode materials are deposited and then removed.

The dam DAM may be disposed on the second bank layer BN2 and may be disposed between the first inorganic encapsulation layers TL1, TL2, and TL3 spaced apart from each other. The dam DAM may be disposed in a space between the first inorganic layer TL1 and the second inorganic layer TL2 spaced apart from each other and a space between the second inorganic layer TL2 and the third inorganic layer TL3 spaced apart from each other.

In a method of providing the display device 10, after the first light emitting layer EL1, the first common electrode CE1, and the first inorganic layer TL1 are formed in the first emission area EA1 (e.g., a first (or previous) emission area structure), the second light emitting layer EL2, the second common electrode CE2, and the second inorganic layer TL2 may be formed in the second emission area EA2 (e.g., as a second (or subsequent) emission area structure). In this case, materials for the subsequent structure are deposited on an entirety of the substrate SUB including the previous structure, and thus, a second light emitting material layer ELL2, a second electrode material layer CEL2, and a second inorganic material layer TLL2 may be formed on the previous structure of the first inorganic layer TL1 covering the first emission area EA1 and the periphery of the first emission area EA1. The second light emitting material layer ELL2 may be made of the same material as the second light emitting layer EL2, and the second electrode material layer CEL2 may be made of the same material as the second common electrode CE2.

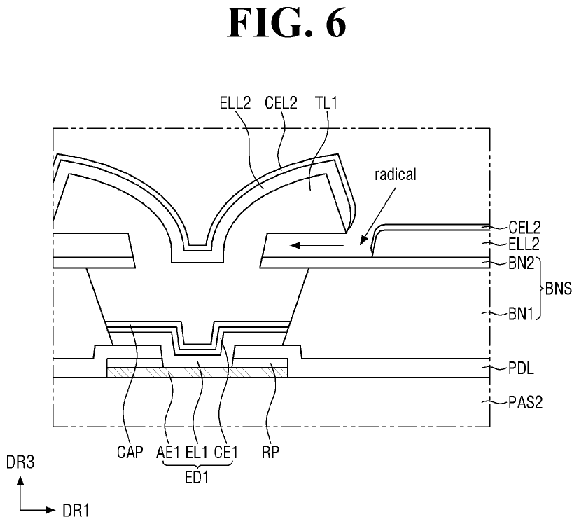

When there is no dam DAM on the second bank layer BN2, due to the undercut structure of the wing portion TL1_W of the first inorganic layer TL1, portions of the second light emitting material layers ELL2 and the second electrode material layers CEL2 are disconnected from each other by such undercut structure and have a gap formed therebetween, at a outer boundary of the first inorganic layer TL1 as illustrated in FIG. 6. After the second inorganic material layer TLL2 is formed above disconnected portions of the second light emitting material layer ELL2 and the second electrode material layer CEL2, only the second organic layer TL2 disposed in the second emission area EA2 and around the second emission area EA2 is left, and the second inorganic material layer TLL2 disposed in the remaining areas is removed through an etching process. In this case, as shown in FIG. 6, a radical of an etchant for removing the second inorganic material layer TLL2 may penetrate into the gap between the second light emitting material layers ELL2 and the second electrode material layers CEL2 that are disconnected from each other. The radical penetrating into the gap removes a portion of the first inorganic layer TL1 and weakens adhesion or encapsulation between the bank structure BNS and the first inorganic layer TL1. This may cause damage to the first light emitting element ED1 and become a dark spot in driving of the display device 10 to display an image.

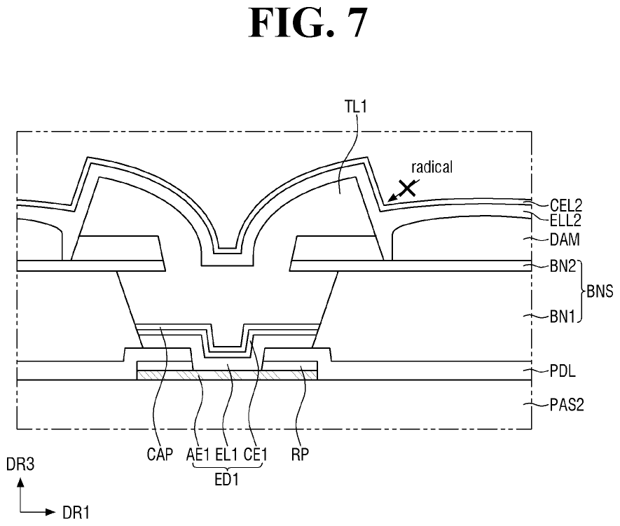

When the dam DAM is disposed on the second bank layer BN2 in a method of providing the display device 10 as illustrated in FIG. 7, the second light emitting material layer ELL2 and the second electrode material layer CEL2 may cover the first inorganic layer TL1 and the dam DAM without being disconnected by the wing of the previous structure. As the dam DAM is disposed to occupy a volume adjacent to an outer edge of the first inorganic layer TL1, step coverage of the second light emitting material layer ELL2 and the second electrode material layer CEL2 may be improved. The first inorganic layer TL1 is surrounded by the second light emitting material layer ELL2 and thus, is not exposed to the etchant during removal of portions of the second inorganic material layer TLL2. Since the first inorganic layer TL1 is covered by the second light emitting material layer ELL2 and the second electrode material layer CEL2, damage to the first light emitting element ED1 may be prevented, and a luminance difference between the light emitting elements ED1, ED2, and ED3 may be reduced.

The dam DAM may not overlap the first inorganic encapsulation layers TL1, TL2, and TL3 in the thickness direction DR3 of the substrate SUB. As not overlapping, the dam DAM and a respective inorganic encapsulation pattern among the first inorganic encapsulation layers TL1, TL2, and TL3 may be adjacent to each other or spaced apart from each other along the second bank layer BN2. The dam DAM is coplanar with the first inorganic encapsulation layers TL1, TL2, and TL3. The first inorganic encapsulation layers TL1, TL2, and TL3 may be spaced apart from the dam DAM by a predetermined distance d1 taken along the second bank layer BN2. The distance d1 between the first inorganic encapsulation layers TL1, TL2, and TL3, and the dam DAM, may be defined as a minimum distance between the first inorganic encapsulation layers TL1, TL2, and TL3 and the dam DAM.

The distance d1 between the first inorganic encapsulation layers TL1, TL2, and TL3 and the dam DAM may be about 0.75 to about 1.25 times the second thickness h2 of the light emitting layers EL1, EL2, and EL3. When the distance d1 is in the above range, coverage of light emitting material layers ELL2 and ELL3 deposited on the first inorganic encapsulation layers TL1, TL2, and TL3 is improved, such that the light emitting material layers ELL2 and ELL3 may fill spaces respectively between the first inorganic encapsulation layers TL1, TL2, and TL3, and the dam DAM closest to an outer edge of such encapsulation patterns. In an embodiment, the distance d1 between the first inorganic encapsulation layers TL1, TL2, and TL3, and the dam DAM, may be about 1000 Å to about 3000 Å.

A maximum vertical distance h3 from the substrate SUB to the upper surface of the dam DAM may be smaller than a minimum vertical distance h4 from the substrate SUB to an upper surface of the first inorganic encapsulation layers TL1, TL2, and TL3. The vertical distance may be a maximum distance or height of the particular element, relative to a reference. The upper surface may be furthest from the reference, such as the substrate SUB, the second bank layer BN2, etc. The height of the dam or a wing portion may be defined at the furthest point or the upper surface, relative to the reference. When a height of the dam DAM is greater than a height of the wing portions TL1_W, TL2_W, and TL3_W of the first inorganic encapsulation layers TL1, TL2, and TL3, the coverage of the light emitting material layers ELL2 and ELL3 deposited on the first inorganic encapsulation layers TL1, TL2, and TL3 may be insufficient. In an embodiment, a first thickness h1 of the dam DAM may be about 1000 Å to about 3000 Å.

The dam DAM may include an organic material. In an embodiment, the dam DAM may include one or more selected from the group consisting of polyimide, polyamide, benzocyclobutene, a phenolic resin, an acrylic resin, a methacrylic resin, polyisoprene, a vinyl-based resin, an epoxy-based resin, a urethane-based resin, a cellulose-based resin, and a perylene-based resin. The dam DAM may include an opaque material as well as a transparent material. The dam DAM may be made of an organic material different from that of the organic encapsulation layer TFE2.

The organic encapsulation layer TFE2 is disposed on the second bank layer BN2, the first inorganic encapsulation layers TL1, TL2, and TL3, and the dam DAM. Portions of the organic encapsulation layer TFE2 may be disposed in spaces between and the wing portions TL1_W, TL2_W, and TL3_W of the first inorganic encapsulation layers TL1, TL2, and TL3 and the upper surface of the second bank layer BN2 spaced apart from each other. Portions of the second bank layer BN2 may not overlap the first to third inorganic layers TL1, TL2, and TL3 and the dam DAM, and may be in direct contact with the organic encapsulation layer TFE2.

The second inorganic encapsulation layer TFE3 may be disposed on the organic encapsulation layer TFE2. The second inorganic encapsulation layer TFE3 may include aluminum oxide, titanium oxide, tantalum oxide, hafnium oxide, zinc oxide, silicon oxide, silicon nitride, and/or silicon oxynitride.

The light blocking layer BM may be disposed on the thin film encapsulation layer TFEL. The light blocking layer BM may include a plurality of holes OPT1, OPT2, and OPT3 defined therein to respectively overlap the emission areas EA1, EA2, and EA3. For example, a first hole OPT1 may be disposed to overlap the first emission area EA1. A second hole OPT2 may be disposed to overlap the second emission area EA2, and a third hole OPT3 may be disposed to overlap the third emission area EA3. An area or a size of each of the holes OPT1, OPT2, and OPT3 may be greater than the area or the size of each of the emission areas EA1, EA2, and EA3. The holes OPT1, OPT2, and OPT3 of the light blocking layer BM are formed to be greater than the emission areas EA1, EA2, and EA3, and accordingly, the light emitted from the emission areas EA1, EA2, and EA3 may be viewed from outside the display device 10, such as by a user, not only from a front surface (e.g., in the third direction DR3 but also from side surfaces of the display device 10.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black, but the present disclosure is not limited thereto. The light blocking layer BM may prevent color mixing duc to permeation of visible light between the first to third emission areas EA1, EA2, and EA3 to improve a color gamut of the display device 10.

The display device 10 may include a plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. For example, the color filters CF1, CF2, and CF3 may be disposed on the light blocking layer BM including the plurality of holes OPT1, OPT2, and OPT3 disposed to correspond to the emission areas EA1, EA2, and EA3. The holes of the light blocking layer BM may be formed to overlap the emission areas EA1, EA2, and EA3 and/or the openings of the bank structures BNS and the pixel defining layer, and may form light emitting areas through which the light emitted from the emission areas EA1, EA2, and EA3 is emitted to outside the display panel 100. Each of the color filters CF1, CF2, and CF3 may have a greater area than each of the holes of the light blocking layer BM, and may completely cover the light emitting area formed by each of the holes.

The color filters CF1, CF2, and CF3 may include a first color filter CF1, a second color filter CF2, and a third color filter CF3 disposed to respectively correspond to the different emission areas EA1, EA2, and EA3. The color filters CF1, CF2, and CF3 may include colorants such as dyes or pigments absorbing light of wavelength bands other than light of a specific wavelength band, and may be disposed to correspond to the colors of the light emitting from the emission areas EA1, EA2, and EA3. For example, the first color filter CF1 may be a red color filter disposed to overlap the first emission area EA1 and transmitting only the first light, which is the red light, therethrough. The second color filter CF2 may be a green color filter disposed to overlap the second emission area EA2 and transmitting only the second light, which is the green light, therethrough, and the third color filter CF3 may be a blue color filter disposed to overlap the third emission area EA3 and transmitting only the third light, which is the blue light, therethrough.

The plurality of color filters CF1, CF2, and CF3 may be spaced apart from other adjacent color filters CF1, CF2, and CF3, along solid portions of the light blocking layer BM. The color filters CF1, CF2, and CF3 may have greater areas than the holes OPT1, OPT2, and OPT3 of the light blocking layer BM while covering the holes OPT1, OPT2, and OPT3 of the light blocking layer BM, respectively, but may have areas enough to be spaced apart from other color filters CF1, CF2, and CF3 on the light blocking layer BM. However, the present disclosure is not limited thereto. The plurality of color filters CF1, CF2, and CF3 may be disposed to partially overlap other adjacent color filters CF1, CF2, and CF3. Different color filters CF1, CF2, and CF3 may overlap each other on a solid portion of a light blocking layer BM to be described later, which is an area that does not overlap the emission areas EA1, EA2, and EA3. In the display device 10, the color filters CF1, CF2, and CF3 are disposed to overlap each other, and accordingly, an intensity of reflected light by external light may be reduced. Furthermore, a color feeling of the reflected light by the external light may be controlled by adjusting an arrangement, shapes, areas, and the like, of the color filters CF1, CF2, and CF3 in plan view.

The overcoat layer OC may be disposed on the color filters CF1, CF2, and CF3 to planarize upper ends of the color filters CF1, CF2, and CF3. The overcoat layer OC may be a colorless light transmitting layer that does not have a color of a visible light band. For example, the overcoat layer OC may include a colorless light transmitting organic material such as an acrylic resin.

Hereinafter, processes for providing the display device 10 according to an embodiment will be described with reference to other drawings.

FIGS. 8 to 18 are detailed cross-sectional views sequentially illustrating processes for providing the display device 10 according to an embodiment.

In FIGS. 8 to 18, processes of forming or providing the bank structure BNS and the light emitting elements ED within the light emitting element layer EML, and the thin film encapsulation layer TFEL which is on the light emitting element layer EML of the display device 10 are schematically illustrated. Hereinafter, a description of processes of forming respective layers among the processes for fabrication of the display device 10 will be omitted, and the order of forming the respective layers will be described.

Referring to FIG. 8, a plurality of pixel electrodes AE1, AE2, and AE3 in a first electrode layer which are spaced apart from each other, sacrificial layers SFL of a sacrificial material layer which are spaced apart from each other, a pixel defining material layer PDLL of a pixel defining layer, and a plurality of bank material layers BNL1 and BNL2 are formed on an entirety of the second passivation layer PAS2.

Although not illustrated in FIG. 8, the thin film transistor layer TFTL may be disposed on the substrate SUB, and a structure of the thin film transistor TFTL is the same as that described above with reference to FIG. 4. A detailed description thereof will be omitted.

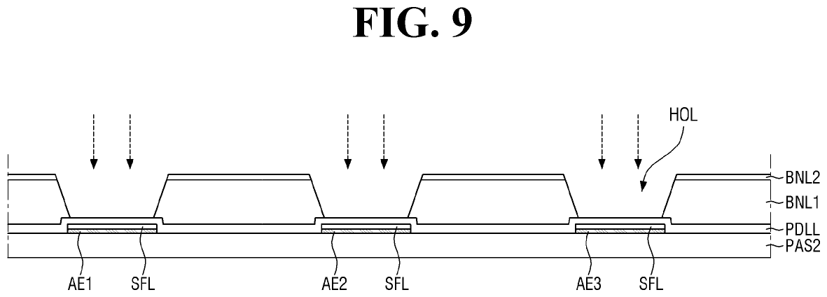

Subsequently, referring to FIG. 9, a photoresist (not illustrated) is formed on a second bank material layer BNL2, and a first etching process (1^{st} etching, downward arrows in FIG. 9) to remove portions of the first and second bank material layers BNL1 and BNL2 using the photoresist PR as a mask is performed. Holes HOL in the first and second bank material layers BNL1 and BNL2 may be formed through the first etching process. The photoresist patterns of the photoresist may be disposed so as to be spaced apart from each other on the second bank material layer BNL2, and may be disposed to expose areas of the second bank material layer BNL2 overlapping the plurality of pixel electrodes AE1, AE2, and AE3.

In an embodiment, anisotropic dry etching may be performed as the first etching process (1^{st} etching). The holes HOL may be formed in the areas overlapping the plurality of pixel electrodes AE1, AE2, and AE3, and may form the openings of the bank structure BNS.

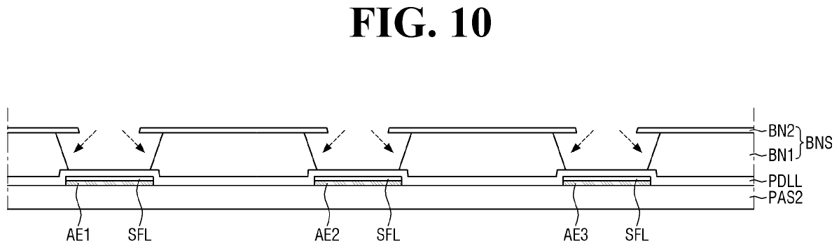

Next, referring to FIG. 10, undercut structures of the first bank layer BN1 may be formed through a second etching process (2nd etching, inclined arrows in FIG. 10). The first bank material layer BNL1 may have a faster etch rate than the second bank material layer BNL2, and inner side surfaces of the second bank layer BN2 may be formed to protrude from the inner side surfaces of the first bank layer BN1. The inner side surfaces of the second bank layer BN2 protrude further than the side surfaces of the first bank layer BN1 and in a direction toward the holes HOL, to form tips TIP. A lower surface of the second bank layer BN2 may be exposed at the tip TIP to define an undercut structure.

In an embodiment, the second etching process may be isotropic wet etching. In the second etching process, an alkali-based etchant may be used. The bank structure BNS including the first and second bank layers BN1 and BN2 may be obtained through the second etching process. Portions of the pixel defining material layer PDLL are exposed to outside the bank structure BNS, at the holes HOL

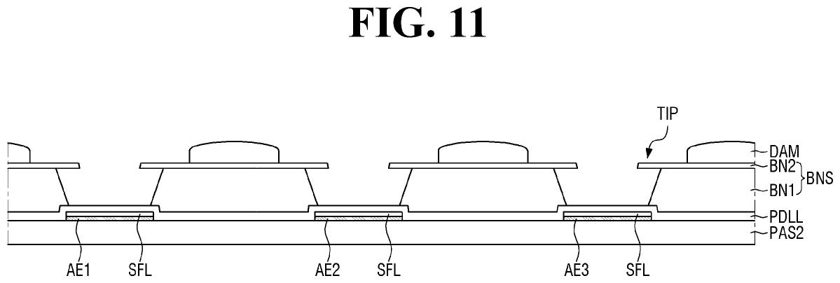

Subsequently, as illustrated in FIG. 11, the dam DAM may be formed on the second bank layer BN2. The forming of the dam DAM may include applying a dam material onto the second bank layer BNL2 through slit coating, spin coating, or inkjet printing and patterning the dam material through photolithography. In the patterning of the dam material, a width of the dam DAM may be adjusted depending on a mask. The organic material as described above may be used as the dam material. The dam DAM may be provided as a discrete pattern, in a plan view.

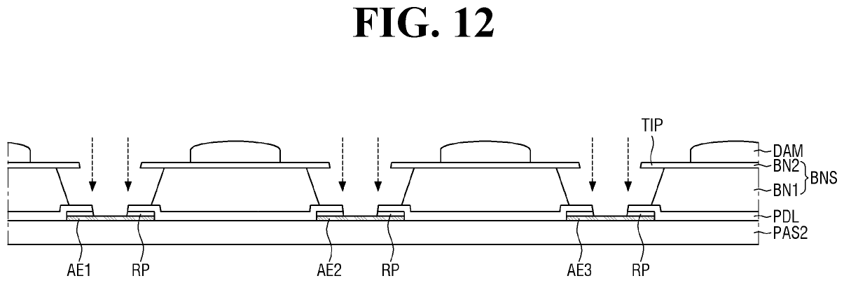

Next, as illustrated in FIG. 12, portions of the pixel defining material layer PDLL may be removed and portions of the sacrificial layers SFL may also be removed, through a third etching process (3^{rd} etching, downward arrows in FIG. 12). The third etching process may include a dry etching process of removing the pixel defining material layer PDLL and a wet etching process of removing the sacrificial layers SFL. The removing of the pixel defining material layer PDLL in the dry etching process may expose portions of the sacrificial layers SFL to outside the pixel defining material layer PDLL, at the holes HOL. The, the wet etching process may remove the portions of the sacrificial layers SFL which are exposed to the holes HOL.

The sacrificial layers SFL may protect the pixel electrodes AE1, AE2, and AE3 from plasma in the dry etching process. Portions of the sacrificial layers SFL exposed to the holes HOL and portions of the sacrificial layers SFL respectively between the first bank material layer BNL1 and each of the pixel electrodes AE1, AE2, and AE3 may be removed. However, the sacrificial layers SFL may not be completely removed, and a residual portion may remain as partial residual patterns RP respectively between the pixel defining film PDL and each of the pixel electrodes AE1, AE2, and AE3.

The pixel electrodes AE1, AE2, and AE3 may be exposed to outside the pixel defining layer, through the third etching process. Thereafter, the photoresist (not illustrated) may be removed.

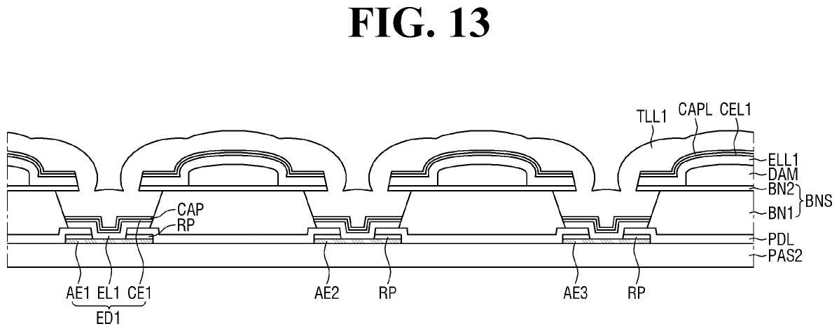

Subsequently, as illustrated in FIG. 13, the first light emitting layer EL1, the first common electrode CE1, and the capping layer CPL are deposited on the first pixel electrode AE1, to form the first light emitting element ED1 in a respective hole HOL. In this case, respective materials of the first light emitting layer EL1, the first common electrode CE1, and the capping layer CAP are formed on the entire surface of the substrate SUB having the dam DAM. Thus, a first light emitting material layer ELL1, a first electrode material layer CEL1, and a capping material layer CAPL may also be formed on the second bank layer BN2 and the dam DAM.

The first light emitting layer EL1 and the first light emitting material layer ELL1 as portions of a same material layer, may be separated from each other by the tips TIP of the second bank layer BN2, the first common electrode CE1 and the first electrode material layer CEL1 as portions of a same material layer, may be separated from each other by the tips TIP of the second bank layer BN2, and the capping layer CAP and the capping material layer CAPL as portions of a same material layer, may be separated from each other by the tips TIP of the second bank layer BN2. The first light emitting layer EL1 is formed on the first pixel electrode AE1, and at the same time, remaining portions of the first light emitting material layer ELL1 may be formed on the second bank layer BN2. The first common electrode CE1 is formed on the first light emitting layer EL1, and at the same time, remaining portions of the first electrode material layer CEL1 may be formed on the first light emitting material layer ELL1. That is, the first light emitting layer EL1 and the first light emitting material layer ELL1 are in a same layer as each other, the first common electrode CE1 and the first electrode material layer CEL1 are in a same layer as each other, and the capping layer CAP and the capping material layer CAPL are in a same layer as each other. As being in a same layer, elements may be formed in a same process and/or as including a same material as each other, elements may be respective portions of a same material layer, elements may be on a same layer by forming an interface with a same underlying or overlying layer, etc., without being limited thereto.

The first light emitting layer EL1 and the first common electrode CE1 may be formed through deposition processes. Materials for the first light emitting layer EL1 and the first common electrode CE1 may not be smoothly deposited within the holes HOL due to the tip TIP of the second bank layer BN2. However, materials of the first light emitting layer EL1 and the first common electrode CE1 are deposited in a direction inclined with an upper surface of the substrate rather than in the direction perpendicular to the upper surface of the substrate, and may thus be deposited in an area and on surfaces effectively hidden by the tip TIP of the second bank layer BN2.

The deposition process of forming the common electrodes CE1, CE2, and CE3 may be performed in an inclined direction relatively closer to a horizontal direction relative to a DR1-DR2 plane, than the deposition process of forming the light emitting layers EL1, EL2, and EL3. Accordingly, the common electrodes CE1, CE2, and CE3 may be in contact with side surfaces of the first bank layer BN1 which define the opening therein in a greater contact area than the light emitting layers EL1, EL2, and EL3. Alternatively, the common electrodes CE1, CE2, and CE3 may be deposited up to a higher position along the side surfaces of the first bank layer BN1 which define the opening therein than the light emitting layers EL1, EL2, and EL3. Different common electrodes CE1, CE2, and CE3 may be in contact with the first bank layer BN1 having high conductivity to be electrically connected to each other via solid portions of the first bank layer BN1.

Subsequently, a first inorganic material layer TLL1 covering the first light emitting element ED1 and the capping layer CAP is formed. The first inorganic material layer TLL1 may be formed to completely cover outer surfaces of the first light emitting element ED1, the bank layers BN1 and BN2, the capping layer CAP, the first light emitting material layer ELL1, the first electrode material layer CEL1, and the capping material layer CAPL without any disconnected portions (e.g., continuously). Specifically, the first inorganic material layer TLL1 is formed on an upper surface of the first common electrode CE1, an upper surface of the capping layer CAP, side surfaces of the first bank layer BN1, a lower surface and an upper surface of the second bank layer BN2, and upper surfaces of the first electrode material layer CEL1 and the capping material layer CAPL.

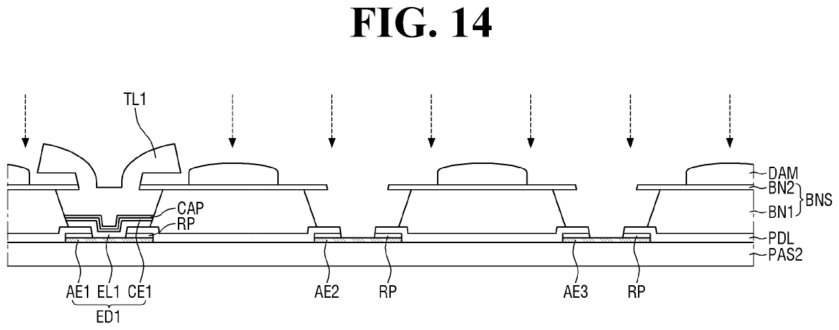

Next, referring to FIG. 14, a fourth etching process (4^{th} etching, downward arrows in FIG. 14) of removing portions of each of the first light emitting material layer ELL1, the first electrode material layer CEL1, the capping material layer CAPL, and the first inorganic material layer TLL1 is performed. In an embodiment, the fourth etching process may include a dry etching process of removing portions of the first inorganic material layer TLL1 and a wet etching process of removing portions of each of the first electrode material layer CEL1 and the first light emitting material layer ELL1.

In the dry etching process, the portions of the first inorganic material layer TLL1 may be removed in an area other than an area overlapping the first emission area EA1 and an edge area surrounding or extending from the first emission area EA1. The first inorganic layer TL1 remains in the area overlapping the first emission area EA1 and extending from the first emission area EA1 to the edge area surrounding the first emission area EA1. Portions of the capping material layer CAPL are also removed to expose the first electrode material layer CEL1.

In the wet etching process, which is isotropic etching, portions of each of the first light emitting material layer ELL1 and the first electrode material layer CEL1 of the second and third emission areas EA2 and EA3 that are not covered with the first inorganic material layer TLL1 as well as the first electrode material layer CEL1 and the first light emitting material layer ELL1 disposed on the second bank layer BN2 and the dam DAM may be removed. Accordingly, the first light emitting material layer ELL1 and the first electrode material layer CEL1 disposed between the wing portion TL1_W of the first inorganic layer TL1 and the second bank layer BN2 may also be removed. Please confirm if the dry or wet etching removes the portions of the capping material layer CAPL.

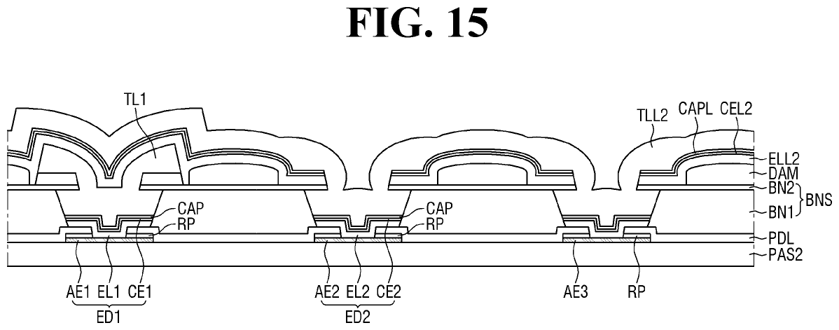

Subsequently, as illustrated in FIG. 15, the second light emitting layer EL2, the second common electrode CE2, and the capping layer CPL are deposited on the second pixel electrode AE2 to form the second light emitting element ED2, on the substrate SUB having the previous emission structure of the first inorganic layer TL1 together with the first light emitting element ED1. Thereafter, the second inorganic material layer TLL2 covering the second light emitting element ED2 and the capping layer CAP is formed. In this process, material layers are deposited on the entire surface of the substrate SUB as in FIG. 13, and the second light emitting material layer ELL2, the second electrode material layer CEL2 and the capping layer CPL may cover the first inorganic layer TL1 and the dam DAM without being disconnected. In particular, the second light emitting material layer ELL2 may also be disposed in a space or gap between the first inorganic layer TL1 and the dam DAM spaced apart from each other. The second light emitting material layer ELL2 may be made of or include the same material as the second light emitting layer EL2.

In FIG. 15, the second light emitting material layer ELL2 extends along the dam DAM closest to the first inorganic layer TL1 and along outer surfaces of the first inorganic layer TL1. The second light emitting material layer ELL2 may remain outside of the gap between the first wing portion TL1_W and the tip TIP of the second bank layer BN2. An empty space or gap may be defined by the first inorganic layer TL1 together with the second bank layer BN2 and the the second light emitting material layer ELL2.

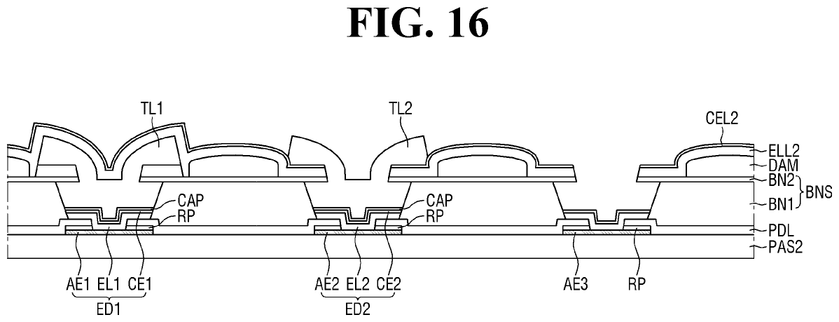

Next, as illustrated in FIG. 16, the second inorganic layer TL2 overlapping the second emission area EA2 and an edge surrounding the second emission area EA2 may be formed by removing a portion of the second inorganic material layer TLL2. This process may be performed similarly to the dry etching process of removing the first inorganic material layer TLL1 of FIG. 14. Portions of the capping material layer CAPL are also removed to expose the second electrode material layer CEL2. Due to the second light emitting material layer ELL2 disposed in the space between the first inorganic layer TL1 and the dam DAM spaced apart from each other, as well as blocking the gap between the first wing portion TL1_W and the tip TIP of the second bank layer BN2, outer surfaces of the first inorganic layer TL1 may not be exposed to etchant plasma, and the first light emitting element ED1 may be protected during the removal of the portions of the second inorganic material layer TLL2.

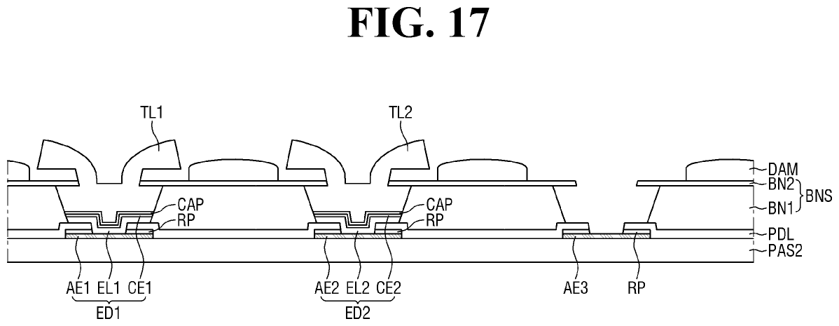

Subsequently, as illustrated in FIG. 17, the second bank layer BN2 and the dam DAM may be exposed by removing the second electrode material layer CEL2 and the second light emitting material layer ELL2 to provide a subsequent emission structure of the second inorganic layer TL2 together with the second light emitting element ED2. This process may be performed similarly to the wet etching process of removing the first electrode material layer CEL1 and the first light emitting material layer ELL1 of FIG. 14.

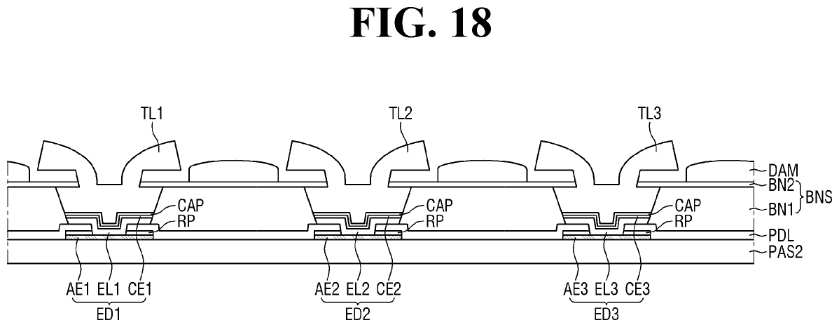

Thereafter, when the processes as illustrated in FIGS. 17 and 18 are similarly performed, the third light emitting element ED3 and the third inorganic layer TL3 together as another subsequent emission structure may be formed on the stacked structure having both the previous emission structure at the first emission area EA1 and the subsequent emission structure at the second emission area EA2.

Subsequently, although not illustrated in the drawings, the display device 10 is further provided by forming the organic encapsulation layer TFE2 and the second inorganic encapsulation layer TFE3 of the thin film encapsulation layer TFEL, the light blocking layer BM, the color filter layer CFL, and the overcoat layer OC on the light emitting elements ED1, ED2, and ED3 and the bank structure BNS. Structures of the thin film encapsulation layer TFEL, the light blocking layer BM, the color filter layer CFL, and the overcoat layer OC are the same as those described above, and a detailed description thereof will thus be omitted.

In one or more embodiment, a display device 10 includes a pixel defining layer defining emission areas including a first emission area EA1 and a second emission area EA2 spaced apart from each other, light emitting elements including a first light emitting element ED1 in the first emission area EA1 and a second light emitting element ED2 in the second emission area EA2, a bank layer BNS on the pixel defining layer and defining openings (e.g., the holes HOL) respectively corresponding to the emission areas, the bank layer including in order from the pixel defining layer a first bank layer BN1 having side surfaces exposed to the openings and a second bank layer BN2 which protrudes further than the side surfaces of the first bank layer BN1, in respective directions towards the emission areas, and includes an upper surface, a first inorganic pattern TL1 in a first opening of the bank layer which corresponds to the first emission area EA1, the first inorganic pattern extending out of the first opening, overlapping a first portion of the second bank layer BN2 which is adjacent to the first emission area EA1, and spaced apart from the upper surface of the second bank layer BN2 at the first portion thereof, a second inorganic pattern TL2 in a second opening of the bank layer which corresponds to the second emission area EA2, the second inorganic pattern TL2 spaced apart from the first inorganic pattern TL1, extending out of the second opening, overlapping a second portion of the second bank layer BN2 which is adjacent to the second emission area EA2, and spaced apart from the upper surface of the second bank layer BN2 at the second portion thereof, and a dam DAM on the second bank layer BN2, the dam DAM being between the first inorganic pattern TL1 and the second inorganic pattern TL2 and spaced apart from both the first inorganic pattern TL1 and the second inorganic pattern TL2.

In a method of providing the display device 10, the method includes providing a layer of pixel electrodes (AE1, AE2, AE3 in FIG. 8) spaced apart from each other and sacrificial layers (SFL in FIG. 8) which are respectively on the pixel electrodes, providing a pixel defining material layer PDLL on the sacrificial layers, the pixel electrodes and spaces therebetween (FIG. 8), providing a bank material layer BNL1 and BNL2 on the pixel defining material layer (FIG. 8), etching the bank material layer at areas overlapping the pixel electrodes to provide a bank layer defining emission area openings HOL which expose the pixel defining material layer to outside the bank layer (BNL1 and BNL2 in FIGS. 9 and 10), the bank layer including a first bank layer BN1 having side surfaces exposed to the emission area openings, and a second bank layer BN2 which is on the first bank layer BN1 and defines tips TIPS of the second bank layer BN2 extended further than the side surfaces of the first bank layer BN1 (FIG. 10), providing a dam DAM on the second bank layer BN2 and spaced apart from the emission area openings (FIG. 11), exposing the pixel electrodes at the emission area openings by etching the pixel defining material layer which is exposed at the emission area openings and etching the sacrificial layers corresponding to the pixel electrodes (FIG. 12), and providing a first light emitting element ED1 including a first pixel electrode AE1 among the pixel electrodes, a first light emitting layer EL1 and a first common electrode CE1, in a first emission area opening (hole HOL at the first emission area EA1) among the emission area openings (FIG. 13), and providing a first inorganic pattern TL1 on the first light emitting element ED1, in the the first emission area opening (FIGS. 13 and 14).

Referring to FIG. 13, the providing of the first light emitting layer EL1 includes providing a first light emitting material layer ELL1 which is on the first pixel electrode AE1, the second bank layer BN2 and the dam DAM and defines the first light emitting layer EL1 which is in the first emission area opening and disconnected from a remainder of the first light emitting material layer by the tips TIP of the second bank layer BN2, the providing of the first common electrode CE1 includes providing a first electrode material layer CEL1 which is on the first light emitting material layer ELL1 and EL1 and defines the first common electrode CE1 which is in the first emission area opening and disconnected from a remainder of the first electrode material layer by the tips TIP of the second bank layer BN2, and the providing of the first inorganic pattern TL1 includes providing a first inorganic material layer TLL1 on the first electrode material layer CEL1 and CE1 and continuously extended from the first common electrode CE1 in the first emission area opening to the dam DAM.

Referring to FIGS. 13 and 14, the method includes etching a portion of the first inorganic material layer TLL1 which corresponds to the remainder of the first electrode material layer CEL1, exposing the dam DAM by etching the remainder of the first electrode material layer CEL1 and the remainder of the first light emitting material layer ELL1. Referring to FIGS. 14-16, the method includes providing a second light emitting element ED2 including a second pixel electrode AE2 among the pixel electrodes, a second light emitting layer EL2 and a second common electrode CE2, in a second emission area opening among the emission area openings which is spaced apart from the first emission area opening with the dam DAM therebetween, and providing a second inorganic pattern TL2 on the second light emitting element ED2, in the second emission area opening.

Referring to FIG. 15, the providing of the second light emitting layer EL2 includes providing a second light emitting material layer ELL2 which is on the first inorganic pattern TL1, the second pixel electrode AE2, the second bank layer BN2 and the dam DAM and defines the second light emitting layer EL2 which is in the second emission area opening and disconnected from a remainder of the second light emitting material layer ELL2 by the tips TIPS of the second bank layer BN2, the providing of the second common electrode CE2 includes providing a second electrode material layer CEL2 which is on the first inorganic pattern TL1, the second light emitting material layer EL2 and ELL2, the second bank layer BN2 and the dam DAM and defines the second common electrode CE2 which is in the second emission area opening and disconnected from a remainder of the second electrode material layer CEL2 by the tips TIPS of the second bank layer, and the providing of the second inorganic pattern TL2 includes providing a second inorganic material layer TLL2 on the first inorganic pattern TL1, the second electrode material layer EL2 and ELL2 and continuously extended from the second common electrode in the second emission area opening to the dam DAM.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A display device comprising:
a pixel defining layer defining emission areas including a first emission area and a second emission area spaced apart from each other;
light emitting elements including a first light emitting element in the first emission area and a second light emitting element in the second emission area;
a bank layer on the pixel defining layer and defining openings respectively corresponding to the emission areas, the bank layer including in order from the pixel defining layer:
a first bank layer comprising side surfaces exposed to the openings; and
a second bank layer which protrudes further than the side surfaces of the first bank layer, in respective directions towards the emission areas, and includes an upper surface;
a first inorganic pattern in a first opening of the bank layer which corresponds to the first emission area, the first inorganic pattern extending out of the first opening, overlapping a first portion of the second bank layer which is adjacent to the first emission area, and spaced apart from the upper surface of the second bank layer at the first portion thereof;
a second inorganic pattern in a second opening of the bank layer which corresponds to the second emission area, the second inorganic pattern spaced apart from the first inorganic pattern, extending out of the second opening, overlapping a second portion of the second bank layer which is adjacent to the second emission area, and spaced apart from the upper surface of the second bank layer at the second portion thereof; and
a dam on the second bank layer, the dam being between the first inorganic pattern and the second inorganic pattern and spaced apart from both the first inorganic pattern and the second inorganic pattern.

2. The display device of claim 1, wherein the dam is coplanar with the first inorganic pattern and the second inorganic pattern.

3. The display device of claim 1, further comprising an organic encapsulation layer on the bank layer,
wherein
a first space is defined between the upper surface of the second bank layer at the first portion thereof and the first inorganic pattern, and a second space is defined between the upper surface of the second bank layer at the second portion thereof and the second inorganic pattern, and
the organic encapsulation layer extends into the first space and the second space.

4. The display device of claim 1, wherein
each of the light emitting elements includes a light emitting layer which has a thickness, and
the dam is spaced apart from the first inorganic pattern by a distance which is about 0.75 to about 1.25 times the thickness of the light emitting layer.

5. The display device of claim 1, wherein the dam is spaced apart from the first inorganic pattern by a distance which is about 1000 angstroms to about 3000 angstroms.

6. The display device of claim 1, wherein each of the light emitting elements includes a light emitting layer which has a thickness of about 1500 angstroms to about 2500 angstroms.

7. The display device of claim 1, wherein in a direction away from the pixel defining layer, along a thickness direction of the display device, the first inorganic pattern protrudes further than the dam.

8. The display device of claim 1, wherein a thickness of the dam is about 1000 angstroms to about 3000 angstroms.

9. The display device of claim 1, wherein
the first light emitting element comprises a first common electrode,
the second light emitting element comprises a second common electrode spaced apart from the first common electrode,
a portion of the first bank layer is between the first opening and the second opening and includes a first side surface exposed to the first opening and a second side surface exposed to the second opening, and
the first common electrode and the second common electrode are respectively in contact with the first and second side surfaces of the first bank layer.

10. The display device of claim 3, wherein the dam includes a material different from a material of the organic encapsulation layer.

11. The display device of claim 1, wherein the dam includes one or more selected from polyimide, polyamide, benzocyclobutene, a phenolic resin, an acrylic resin, a methacrylic resin, polyisoprene, a vinyl-based resin, an epoxy-based resin, a urethane-based resin, a cellulose-based resin and a perylene-based resin.

12. The display device of claim 1, wherein
the second bank layer which protrudes further than the side surfaces of the first bank layer defines a tip including a lower surface exposed to the first and second openings,
the first light emitting element comprises a first common electrode,
the second light emitting element comprises a second common electrode spaced apart from the first common electrode,
the first inorganic pattern is in contact with the lower surface of the second bank layer within the first opening, and
the second inorganic pattern is in contact with the lower surface of the second bank layer within the second opening.

13. The display device of claim 1, wherein
each of the light emitting elements includes a pixel electrode having an upper surface, and
the pixel defining layer is spaced apart from the upper surface of the pixel electrode.

14. The display device of claim 13, further comprising
a space between the pixel defining layer and the upper surface of the pixel electrode, and
a residual pattern in the space.

15. A method for providing a display device, the method comprising:
providing a layer of pixel electrodes spaced apart from each other and sacrificial layers which are respectively on the pixel electrodes,
providing a pixel defining material layer on the sacrificial layers, the pixel electrodes and spaces therebetween,
providing a bank material layer on the pixel defining material layer;
etching the bank material layer at areas overlapping the pixel electrodes to provide a bank layer defining emission area openings which expose the pixel defining material layer to outside the bank layer, the bank layer including:
a first bank layer having side surfaces exposed to the emission area openings, and
a second bank layer which is on the first bank layer and defines tips of the second bank layer extended further than the side surfaces of the first bank layer;
providing a dam on the second bank layer and spaced apart from the emission area openings;
exposing the pixel electrodes at the emission area openings by etching the pixel defining material layer which is exposed at the emission area openings and etching the sacrificial layers corresponding to the pixel electrodes; and
providing a first light emitting element including a first pixel electrode among the pixel electrodes, a first light emitting layer and a first common electrode, in a first emission area opening among the emission area openings, and
providing a first inorganic pattern on the first light emitting element, in the the first emission area opening.

16. The method of claim 15, wherein the providing of the dam includes:
providing a material of the dam onto the second bank layer through slit coating, spin coating or inkjet printing, and
patterning the material of the dam through photolithography.

17. The method of claim 15, wherein
the providing of the first light emitting layer includes providing a first light emitting material layer which is on the first pixel electrode, the second bank layer and the dam and defines the first light emitting layer which is in the first emission area opening and disconnected from a remainder of the first light emitting material layer by the tips of the second bank layer,
the providing of the first common electrode includes providing a first electrode material layer which is on the first light emitting material layer and defines the first common electrode which is in the first emission area opening and disconnected from a remainder of the first electrode material layer by the tips of the second bank layer, and
the providing of the first inorganic pattern includes providing a first inorganic material layer on the first electrode material layer and continuously extended from the first common electrode in the first emission area opening to the dam.

18. The method of claim 17, further comprising:
etching a portion of the first inorganic material layer which corresponds to the remainder of the first electrode material layer;
exposing the dam by etching the remainder of the first electrode material layer and the remainder of the first light emitting material layer; and
providing a second light emitting element including a second pixel electrode among the pixel electrodes, a second light emitting layer and a second common electrode, in a second emission area opening among the emission area openings which is spaced apart from the first emission area opening with the dam therebetween; and
providing a second inorganic pattern on the second light emitting element, in the second emission area opening.

19. The method of claim 18, wherein
the providing of the second light emitting layer includes providing a second light emitting material layer which is on the first inorganic pattern, the second pixel electrode, the second bank layer and the dam and defines the second light emitting layer which is in the second emission area opening and disconnected from a remainder of the second light emitting material layer by the tips of the second bank layer,
the providing of the second common electrode includes providing a second electrode material layer which is on the first inorganic pattern, the second light emitting material layer, the second bank layer and the dam and defines the second common electrode which is in the second emission area opening and disconnected from a remainder of the second electrode material layer by the tips of the second bank layer, and
the providing of the second inorganic pattern includes providing a second inorganic material layer on the first inorganic pattern, the second electrode material layer and continuously extended from the second common electrode in the second emission area opening to the dam.

20. The method of claim 18, wherein
the etching of the portion of the first inorganic material layer comprises a dry etching process, and
the etching of the remainder of the first electrode material layer and the remainder of the first light emitting material layer comprises a wet etching process.
